(19) United States
(12) Patent Application Publication
(10) Pub. No.: US 2009/0125272 A1
(43) Pub. Date: May 14, 2009

(54) METHOD FOR ANALYZING CIRCUIT

(76) Inventors: Hsin-Lan CHANG, Taiwan (CN); Tai-Cheng Lee, Taiwan (CN); Sheng-Yow Chen, Taiwan (CN)

Correspondence Address: Muncy, Geissler, Olds & Lowe, PLLC, P.O. BOX 1364, FAIRFAX, VA, 22038-1364, US

(21) Appl. No.: 12/267,194

(22) Filed: Nov. 7, 2008

Related U.S. Application Data
(60) Provisional application No. 60/986,468, filed on Nov. 8, 2007.

(51) Int. Cl. G01R 31/00; G06F 17/18

(52) U.S. Cl. 702/117; 702/179

(57) ABSTRACT

A method for analyzing circuit comprises the steps of selecting a plurality of elements; sampling the selected elements, resulting in a plurality of sampling-parameter sets; simulating the sampling-parameter sets to generate a plurality of simulation-results, and process the regression operation for the sampling-parameter sets and simulation-results in order to acquire the contribution rank of each sampling-parameter set and element. Accordingly, while analyzing similar circuits, the partial elements can be selected according to the contribution rank and further sampled; thereby, the amount of sampling-parameter sets can be advantageously reduced, and the analysis efficiency can be improved according to the circuit.

### FIELD OF THE INVENTION

The present invention relates to a method for analyzing circuit, and more particularly to a method for analyzing circuit that processes the operation for the sample-parameter sets and simulation-results to acquire the contribution rank of each element.

### BACKGROUND OF THE INVENTION

Referring to FIG. 1, a flow chart illustrating the method for analyzing circuit according to the prior art is shown. As show in step 11, while analyzing the circuit, the elements thereof should at first be sampled, and further, a plurality of sampling-parameter sets have to be generally generated. For example, regarding the Monte Carlo Sampling method, each sample-parameter set corresponds to one of the elements, wherein each sample-parameter set comprises a plurality of parameters.

As shown in step 13, the sampling-parameter sets should be further simulated to obtain a plurality of simulating-results. For example, the simulator simulates the sample-parameter sets, and generates the corresponding simulation-results. As shown in step 15, the user can further analyze and apply for the sample-parameter sets and simulation-results.

In order to improve upon the correction of the simulating-results, a greater quantity of sample-parameter sets should be considered; however, the difficulty and time spent will be increased accordingly for the simulation. For example, the user should sample each different circuit and each sample-parameter to obtain the simulation-result.

### SUMMARY OF THE INVENTION

Therefore, an objective of the present invention is to provide a method for analyzing circuit, which processes the regression operation for the sample-parameter sets and simulation-results to obtain the contribution rank of each element and the sample-parameter sets.

Another objective of the present invention is to provide a method for analyzing circuit, which has the contribution rank of each element of the circuit in accordance with the result of the regression operation. Thereby, the element selected can be processed for the similar circuit in accordance with the contribution rank; therefore, the amount of required sample-elements can be reduced accordingly.

Another objective of the present invention is to provide a method for analyzing circuit, which improves the efficiency of analysis for the similar circuit since the amount of required sample-elements and the amount of required sample-parameter sets for simulation are reduced.

Another objective of the present invention is to provide a method for analyzing circuit, wherein the specific sample-parameter set can be eliminated since the specific sample-parameter set corresponds to the lowest contribution rank according to the result of the regression operation, thereafter, the regression operation will be processed again for the rest of sample-parameter sets and simulation-results, thereby, the errors of eliminating the higher contribution rank can be prevented during the operation process.

Another objective of the present invention is to provide a method for analyzing circuit, wherein the general four arithmetic operations can be used for eliminating the multiple ratios between each parameter of the sample-parameter set, such that the parameters can be efficiently sampled.

In an aspect of the present invention, a method for analyzing circuit is provided, comprising the steps of sampling a plurality of elements and further generating a plurality of sample-parameter sets; simulating the sample-parameter sets and further generating a plurality of simulation-results; and processing the regression operation for the sample-parameter sets and the simulation-results, and further calculating the contribution rank of said sample-parameter set.

### BRIEF DESCRIPTION OF THE DRAWINGS

The accompanying figures, like reference numerals, refer to identical or functionally similar elements throughout separate views and which, together with the detailed description below, are incorporated in and form part of the specification, serve to further illustrate various embodiments, and to explain various principles and advantages in accordance with the present invention.

FIG. 1 shows a flow chart illustrating the method for analyzing circuit according to a prior art;

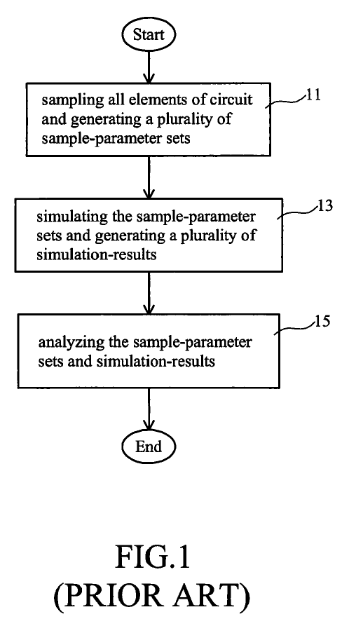

FIG. 2 shows a flow chart illustrating a method for analyzing circuit according to a preferred embodiment of the present invention;

FIG. 3 shows a flow chart illustrating a method for analyzing circuit according to another preferred embodiment of the present invention; and

FIG. 4 shows a flow chart illustrating a method for analyzing circuit according to another preferred embodiment of the present invention.

### DETAILED DESCRIPTION OF DISCLOSED EMBODIMENTS

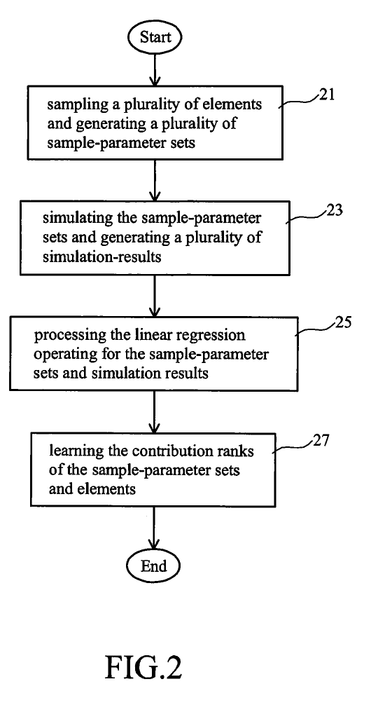

Referring to FIG. 2, a flow chart illustrating a method for analyzing circuit according to a preferred embodiment of the present invention is disclosed. The method for analyzing circuit according to the present invention is characterized by having the simulation-results and the contribution ranks of the elements regarding the regression operation processed for a plurality of sample-parameter sets and a plurality of simulation-results.

As shown in step 21, a plurality of elements of the circuit are selected and sampled, such as by way of Monte Carlo Sampling, Latin-Hypercube Sampling (LHS), or others. Further, a plurality of sample-parameter sets will be generated, which correspond with the elements. Otherwise, users can practically sample the elements partially or completely in accordance with their experience. As show in step 23, the simulator can be used to simulate a plurality of sample-parameter sets for generating a plurality of corresponding simulation-results. Certainly, the more sample-parameter sets provided, the more corrective the simulation-results will be.

As shown in step 25, the regression operation can be further processed for the sample-parameter sets and simulation-results. Thereafter, as shown in step 27, the contribution rank of each element and each sample-parameter set can be obtained according to the regression operation, wherein the sample-parameter set corresponds with the element of circuit. Therefore, the contribution rank of the element can be learned in accordance with the contribution rank of the sample-parameter set. Accordingly, the formula of the linear regression operation is as follows:

$$A = [ \begin{matrix}0.4405 & 0.8547 \\ 0.8514 & 0.3007 \\ 0.6539 & 0.5038 \\ 0.2375 & 0.0145\end{matrix} ] B = [ \begin{matrix}18.1153 \\ 7.0564 \\ 11.1091 \\ 1.3013\end{matrix} ]$$

Matrix A is the sample-parameter set, and matrix B is the simulation-result for the sample-parameter set, wherein each sample-parameter set comprises a plurality of parameters. Regarding the present embodiment, the first sample-parameter set and the second sample-parameter set all comprise four parameters, for example, the first sample-parameter set comprises the parameters 0.4405, 0.8514, 0.6539, and 0.2375; as well, the second sample-parameter set comprises the parameters 0.8547, 0.3007, 0.5038, and 0.0145. The first row of matrix A is the first sample-parameter set (0.4405, 0.8514, 0.6539, and 0.2375), and the second row of matrix A is the second sample-parameter set (0.8547, 0.3007, 0.5038, and 0.0145). Matrix A can be further inserted in one constant row to become matrix A1:

$$A 1 = [ \begin{matrix}1 & 0.4405 & 0.8547 \\ 1 & 0.8514 & 0.3007 \\ 1 & 0.6539 & 0.5038 \\ 1 & 0.2375 & 0.0145\end{matrix} ]$$

Matrix A1 is transposed to become a transposed matrix A1^{T}; thereafter, the transposed matrix A1^{T} multiplies matrix A1:

$$A {1}^{T} A 1 = [ \begin{matrix}4 & 2.1833 & 1.6736 \\ 2.1833 & 1.4029 & 0.9654 \\ 1.6736 & 0.9654 & 1.0749\end{matrix} ]$$

And, the inverse of matrix A1^{T}A1 is matrix (A1^{T}A1)⁻¹:

$${( A {1}^{T} A 1 )}^{- 1} = [ \begin{matrix}1.8842 & - 2.3916 & - 0.7859 \\ - 2.3916 & 4.9014 & - 0.6783 \\ - 0.7859 & - 0.6783 & 2.7631\end{matrix} ]$$

Matrix (A1^{T} A1)⁻¹ multiplies transposed matrix A1^{T}:

$${( A {1}^{T} A 1 )}^{- 1} A {1}^{T} = [ \begin{matrix}0.159 & - 0.3883 & - 0.0755 & 1.3048 \\ - 0.8121 & 1.5777 & .04715 & - 1.2371 \\ 1.2769 & - 0.5326 & 0.1627 & - 0.907\end{matrix} ]$$

Matrix (A1^{T}A1)⁻¹A1^{T} further multiplies matrix B:

$${( A {1}^{T} A 1 )}^{- 1} A {1}^{T} B = [ \begin{matrix}1 \\ 0.05 \\ 20\end{matrix} ]$$

At this time, the linear regression operation is finished; thereafter, the constant of matrix (A1^{T}A1)-A1^{T}B can be eliminated for obtaining matrix I:

$$I = [ \begin{matrix}0.05 \\ 20\end{matrix} ]$$

Furthermore, matrix A and matrix I will be compared:

$$A = [ \begin{matrix}0.4405 & 0.8547 \\ 0.8514 & 0.3007 \\ 0.6539 & 0.5038 \\ 0.2375 & 0.0145\end{matrix} ] I = [ \begin{matrix}0.05 \\ 20\end{matrix} ]$$

The contribution rank of the first sample-parameter set with respect to the first row of matrix A (0.4405, 0.8514, 0.6539, and 0.2375) is 0.05, and the contribution rank of the second sample-parameter set with respect to the second row of matrix B (0.8547, 0.3007, 0.5038, and 0.0145) is 20. Therefore, the contribution rank of the second sample-parameter set is larger than the first sample-parameter set. Furthermore, the values of I might be negative. The contribution is its absolute value.

Generally, the parameters of the sample-parameter set are generated by random process, therefore, while the correlation between each parameter occurs, the correlation should be eliminated to improve the correction of the simulation. For example, while a multiple ratio occurs between each parameter, the multiple ratios can be eliminated by the four arithmetic operations in regards to at least one parameter. In another embodiment of the invention, the correlation between each parameter can be eliminated by statistic sampling methods.

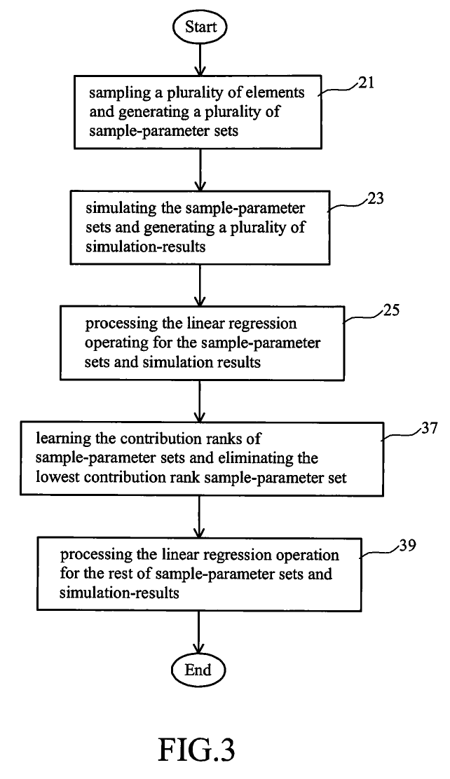

Referring to FIG. 3, a flow chart illustrating a method for analyzing circuit according to another preferred embodiment of the present invention is disclosed. Recalling the foregoing embodiment, there are only two sample-parameter sets; however, the amount of the sample-parameter sets will be larger than two, practically; therefore, the detailed description for more than two sample-parameter sets is further illustrated as follows.

As shown in step 21, similarly, a plurality of elements should be selected before circuit analysis, and further, the selected plurality of elements can be sampled to generate a plurality of sample-parameter sets. As shown in step 23, the plurality of sample-parameter sets will be simulated to generate a plurality of simulation-results. As shown in step 25, the regression operation can be further processed for the sample-parameter sets and simulation-results.

The present embodiment shows more than two sample-parameter sets. However, although the contribution rank of each sample-parameter set can be learned by the regression operation, the regression operation can be processed a large number of times as well to improve the correction of the simulation. For example, since the first regression operation is processed for the sample-parameter sets and simulation-results, the result of the first regression operation can be learned for the contribution rank of each sample-parameter set, and further, the specific sample-parameter sets can be selected to be eliminated, wherein the specific sample-parameter set has the lowest contribution rank, as shown in step 37.

As shown in step 39, the second regression operation will be processed for the rest of the sample-parameter sets and simulation-results after eliminating specific sample-parameter sets. Therefore, the regression operation can be processed a number of times, practically, and specific sample-parameter sets can be eliminated step-by-step according to the results of the operation, thereby, the sample-parameter sets and elements with higher contribution ranks can be picked over gradually.

Certainly, more than one sample-parameter set can be eliminated in accordance with the result of the regression operation due to the requirement of operation efficiency. Thereafter, the regression operation will be processed again for the rest of the sample-parameter sets and simulation-results. For example, the two lowest contribution rank sample-parameter sets can be selected for elimination, and further, the regression operation will be processed one more time.

Besides, the specific sample-parameter set can be compared with other sample-parameter sets according to the results of a regression operation; accordingly, the comparison result can be used to determine whether the specific sample-parameter set should be eliminated or not, or whether the regression operation should be processed continuously or not. For example, the contribution rank of the specific sample-parameter set can be compared with the average of others; surely, it can also be compared with the average of the higher contribution ranks of sample-parameter sets. Accordingly, if the comparison result is smaller than 1:10, the lowest contribution rank sample-parameter set can be eliminated; thereafter, the regression operation will be continuously processed for the rest of the sample-parameter sets and simulation-results; however, if the comparison result is larger than 1:10, the lowest contribution rank sample-parameter is without necessity to be eliminated, and the regression operation is also without processing.

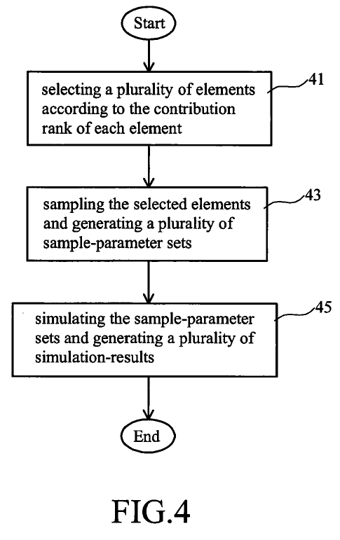

Referring to FIG. 4, a flow chart illustrating a method for analyzing circuit according to another preferred embodiment of the present invention is disclosed. IC designers usually modify the original circuit in order to close in on their ideal during the circuit design period; otherwise, the modified circuits might be applied to a similar device. The method for analyzing circuit regarding the present invention can reveal the contribution ranks of the main elements of the original circuit. Therefore, once the modified circuit is similar to the original circuit, the contribution ranks of the main elements of the original circuit can be used for reference. Further, the modified circuit can be analyzed according to the contribution ranks of the main elements. Thereby, the analysis efficiency for circuits can be improved accordingly.

After analyzing the original circuit and processing of the regression operation more than once, the contribution ranks of the main elements of the original circuit will be obtained; thereafter, the same elements will be picked from the similar circuit according to their contribution ranks, thereby, the required amount of sampling elements will be reduced, as shown in step 41. Therefore, as shown in step 43, the selected elements can be sampled to generate a plurality of corresponding sample-parameter sets, wherein the amount of sample-parameter sets will be reduced since the corresponding sampling of elements are reduced accordingly. Finally, as shown in step 45, the plurality of sample-parameter sets will be continuously simulated to generate a plurality of corresponding simulation-results.

Due to the modified circuit and original circuit being similar, the elements used within the original circuit may affect the similar circuit, such as the modified circuit, in accordance with the information learned from the contribution ranks of the main elements of the original circuit. Therefore, while analyzing the similar circuit, there are only partial elements that will be sampled. Further, the sample-parameter sets will be simulated, thereby, the amount of sampling elements and sample-parameter sets will be efficiently reduced. Accordingly, the time spent analyzing a similar circuit will surely be shortened.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was/were chosen and described to provide the best illustration of the principles of the invention and its practical application, and to enable one of ordinary skills of the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

What is claimed is:

1. A method for analyzing circuit, comprising the steps of:
sampling a plurality of elements and further generating a plurality of sample-parameter sets;
simulating said sample-parameter sets and further generating a plurality of simulation-results; and
processing the regression operation for said sample-parameter sets and said simulation-results and further calculating the contribution rank of said sample-parameter set.

2. The method for analyzing circuit of claim 1, further comprising the step of:
eliminating the specific sample-parameter set, wherein said specific sample-parameter set is corresponding to the lowest contribution rank.

3. The method for analyzing circuit of claim 2, wherein the amount of said specific sample-parameter sets is equal to or more than one.

4. The method for analyzing circuit of claim 2, further comprising the step of:
processing the regression operation for the rest of said sample-parameter sets and said simulation-results.

5. The method for analyzing circuit of claim 1, further comprising the step of:
comparing said specific sample-parameter set with other sample-parameter sets.

6. The method for analyzing circuit of claim 5, further comprising the step of:
determining whether said specific sample-parameter set should be eliminated or not according to the comparison result.

7. The method for analyzing circuit of claim 1, wherein each sample-parameter set comprises a plurality of parameters.

8. The method for analyzing circuit of claim 7, further comprising the step of:
eliminating the correlation between each parameters by statistic sampling methods.

9. The method for analyzing circuit of claim 7, further comprising the step of:
eliminating the correlation between each parameter.

10. The method for analyzing circuit of claim 7, wherein a multiple ratio is provided between each parameter, and said multiple ratio can be eliminated by the four arithmetic operations.

11. The method for analyzing circuit of claim 1, wherein said sample-parameter set corresponds with said element, and the contribution rank of said element can be learned in accordance with the contribution rank of said sample-parameter set.

12. The method for analyzing circuit of claim 10, further comprising the step of:
analyzing circuit according to the contribution rank of said element.

13. The method for analyzing circuit of claim 1, wherein said sample-parameter sets and said simulation-results are matrixes.
